(19) United States
(12) Patent Application Publication
(10) Pub. No.: US 2026/0145540 A1
(43) Pub. Date: May 28, 2026

(54) SYSTEMS AND METHODS FOR INTELLIGENT BATTERY THERMAL RUNAWAY DETECTION

(71) Applicant: Hyroad Networks LLC, Austin, TX (US)

(72) Inventors: Shaikh Tofazzel Hossain, Phoenix, AZ (US); Matthias Bergmann, Phoenix, AZ (US); Tina Han, Phoenix, AZ (US); Jaeseung Lee, Phoenix, AZ (US)

(73) Assignee: Hyroad Networks LLC, Austin, TX (US)

(21) Appl. No.: 19/399,897

(22) Filed: Nov. 25, 2025

Related U.S. Application Data
(60) Provisional application No. 63/724,493, filed on Nov. 25, 2024.

(51) Int. Cl. B60L 3/08; B60L 3/00; B60L 50/64; B60L 58/26; G01R 31/367; G01R 31/392; G01R 31/396; G07C 5/04; H01M 10/42; H01M 10/613; H01M 10/625; H01M 10/633

(52) U.S. Cl. CPC B60L 3/08; B60L 3/0046; B60L 50/64; B60L 58/26; G01R 31/367; G01R 31/392; G01R 31/396; G07C 5/04; H01M 10/425; H01M 10/613; H01M 10/625; H01M 10/633; B60L 2240/12; B60L 2240/547; B60L 2240/549; B60L 2240/70; H01M 2010/4271; H01M 2220/20

(57) ABSTRACT

A method for early detection of a thermal runaway fault for a high voltage battery system of a vehicle is disclosed. The method may include receiving, by a battery fault detection system, historical operational data associated with the high voltage battery system of the vehicle, preparing the historical operational data for input into a trained predicted operation model, modeling predicted operational data of the high voltage battery system based on the historical operational data, comparing the historical operational data and the predicted operational data, and determining the thermal runaway fault based on the comparison between the historical operational data and the predicted operational data.

### CROSS-REFERENCE TO RELATED APPLICATION

This application claims priority to, and the benefit of, U.S. Provisional Patent Application No. 63/724,493 filed on Nov. 25, 2024 entitled “Systems and Methods for Intelligent Battery Thermal Runaway Detection.” The disclosure of the foregoing application is incorporated herein by reference in its entirety, including but not limited to those portions that specifically appear hereinafter, but except for any subject matter disclaimers or disavowals, and except to the extent that the incorporated material is inconsistent with the express disclosure herein, in which case the language in this disclosure shall control.

### TECHNICAL FIELD

The present disclosure relates generally to electric vehicles and, more particularly, to methods and systems used to determine and communicate information concerning the status and/or health of an electric vehicle battery system.

### BACKGROUND

Battery electric vehicles (BEVs) and fuel cell electric vehicles (FCEVs) often include high voltage battery systems configured to store and release electrical energy to power the vehicle. These high voltage battery systems often contain a plurality of cells, which can be electrically coupled to form a plurality of modules, which can be electrically coupled to form a plurality of battery packs. For a variety of reasons (such as, for example, overcharging, overdischarging, physical damage, manufacturing defects, and the like), one or more cells may become damaged, increasing the likelihood of thermal runaway, and posing a safety concern for operators, passengers, and first responders. Accordingly, there is a need for systems and methods capable of early detection of battery characteristics indicative of heightened thermal runaway risk.

### SUMMARY

In an exemplary embodiment, a method comprises receiving, by a battery fault detection system, historical operational data associated with a high voltage battery system of a vehicle, wherein the historical operational data comprises at least one of a maximum cell voltage or a minimum cell voltage; preparing, by the battery fault detection system, the historical operational data for input into a trained predicted operation model; modeling, by the trained predicted operation model, predicted operational data of the high voltage battery system based on the historical operational data, wherein the predicted operational data comprises at least one of a predicted maximum cell voltage or a predicted minimum cell voltage; comparing, by the battery fault detection system, the historical operational data and the predicted operational data; determining, by the battery fault detection system, the existence of a thermal runaway fault based on the comparison between the historical operational data and the predicted operational data; and based on the determining the existence of a thermal runaway fault, transmitting, by the battery fault detection system, a thermal runaway fault message.

The method may further comprise receiving, by the battery fault detection system, initial characterization data associated with the high voltage battery system, wherein the initial characterization data includes data regarding one or more components of the high voltage battery system, and wherein the modeling predicted operational data is based at least in part on the initial characterization data. The method may further comprise communicating, by the battery fault detection system and to a user application associated with a user of the vehicle, the thermal runaway fault message.

The high voltage battery system may comprise: a battery management system (BMS); and a plurality of battery packs, each battery pack in the plurality of battery packs comprising a plurality of battery modules, each battery module in the plurality of battery modules comprising a plurality of battery blocks, and each battery block in the plurality of battery blocks comprising a plurality of battery cells. The thermal runaway fault may identify a specific battery pack in the plurality of battery packs as a faulted battery pack.

The method may further comprise disconnecting, by the BMS, the faulted battery pack from the remaining battery packs in the plurality of battery packs. The method may further comprise at least partially discharging the faulted battery pack to below a threshold state of charge (SOC). The at least partially discharging the faulted battery pack may comprise using the faulted battery pack to at least partially charge one or more of the other battery packs in the plurality of battery backs. The at least partially discharging the faulted battery pack may comprise delivering current from the faulted battery pack to a brake resistor of the vehicle. The at least partially discharging the faulted battery pack may comprise delivering current from the faulted battery pack to operate at least one of a pump or a fan of the vehicle.

The method may further comprise setting, by a vehicle control module of the vehicle, the vehicle into a “limp-home” mode whereby at least one of current draw from the high voltage battery system or top speed of the vehicle are limited. The method may further comprise increasing, responsive to the thermal runaway fault and by a thermal management system of the vehicle, cooling of the high voltage battery system to reduce the temperature of one or more components thereof.

The trained predicted operation model may comprise a convolutional neural network (CNN) or a long short-term memory (LSTM) deep learning algorithm. The historical operational data may be obtained through a measurement obtained by a plurality of sensors in the high voltage battery system. Each sensor in the plurality of sensors may be coupled directly or indirectly to a corresponding battery cell. Receiving, by the battery fault detection system, historical operational data may comprise receiving the historical operational data from an electronic control unit (ECU) of the vehicle.

Preparing, by the battery fault detection system, the historical operational data may comprise comparing a difference between the maximum cell voltage and the minimum cell voltage to a voltage threshold, and preparing, by the battery fault detection system, the historical operational data may comprise adding, by the battery fault detection system, the voltage threshold to the minimum cell voltage to determine an adjusted maximum cell voltage. Preparing, by the battery fault detection system, the historical operational data may comprise subtracting, by the battery fault detection system, the voltage threshold from the maximum cell voltage to determine an adjusted minimum cell voltage.

The battery fault detection system and the trained prediction operation model may be operative on one or more processors onboard the vehicle. The battery fault detection system and the trained prediction operation model may be disposed remotely from the vehicle and may be in communicative connection therewith via a secure wireless network connection.

The contents of this section are intended as a simplified introduction to the disclosure and are not intended to limit the scope of any claim. The foregoing features and elements may be combined in various combinations without exclusivity, unless expressly indicated otherwise. These features and elements as well as the operation thereof will become more apparent in light of the following description and the accompanying drawings. It should be understood, however, the following description and drawings are intended to be exemplary in nature and non-limiting.

### BRIEF DESCRIPTION OF THE DRAWINGS

The accompanying drawings are included to provide a further understanding of the present disclosure and are incorporated in, and constitute a part of, this specification, illustrate various embodiments, and together with the description, serve to explain exemplary principles of the disclosure.

FIG. 1 illustrates components of an exemplary FCEV, in accordance with various embodiments;

FIG. 2 illustrates an exemplary high voltage battery system for use in an FCEV or BEV, in accordance with various embodiments;

FIG. 3 illustrates a method for identifying a battery thermal runaway fault, in accordance with various embodiments;

FIG. 4 illustrates further details of the method illustrated in FIG. 3, in accordance with various embodiments;

FIG. 5 illustrates further details of the method illustrated in FIG. 3, in accordance with various embodiments;

FIGS. 6A and 6B illustrate exemplary operational data associated with a healthy battery pack, in accordance with various embodiments;

FIGS. 7A and 7B illustrate exemplary operational data associated with a faulted battery pack, in accordance with various embodiments; and

FIGS. 8A and 8B illustrate exemplary operational data associated with a faulted battery pack, in accordance with various embodiments.

### DETAILED DESCRIPTION

The detailed description of various embodiments herein makes reference to the accompanying drawings, which show various embodiments by way of illustration. While these various embodiments are described in sufficient detail to enable those skilled in the art to practice the disclosure, it should be understood that other embodiments may be realized and that logical, chemical, electrical, communicative, or mechanical changes may be made without departing from the spirit and scope of the disclosure. Thus, the detailed description herein is presented for purposes of illustration only and not of limitation.

For example, the steps recited in any of the method or process descriptions may be executed in any suitable order and are not necessarily limited to the order presented. Moreover, not all steps may be present in any particular embodiment. Furthermore, any reference to singular includes plural embodiments, and any reference to more than one component or step may include a singular embodiment or step. Also, any reference to attached, fixed, connected, coupled, or the like may include permanent, removable, temporary, partial, full, and/or any other possible attachment option. Additionally, any reference to without contact (or similar phrases) may also include reduced contact or minimal contact.

For example, in the context of the present disclosure, methods, systems, and articles may find particular use in connection with BEVs, FCEVs, compressed natural gas (CNG) vehicles, hythane (mix of hydrogen and natural gas) vehicles, and/or the like. As used herein, “vehicle” may refer to a light-duty, medium duty, or heavy-duty commercial vehicle, passenger vehicle, or any other vehicle. However, various aspects of the disclosed embodiments may be adapted for performance in a variety of other systems. Further, in the context of the present disclosure, methods, systems, and articles may find particular use in any system requiring use of a battery. As such, numerous applications of the present disclosure may be realized.

While principles of the present disclosure are discussed primarily in relation to fault identification in high voltage components and systems, it should be appreciated that the principles described herein may also apply to or make use of low voltage components/systems. As referred to herein, “high voltage” means an electric component or circuit having a working voltage of at least 100 V, at least 200 V, at least 400 V, or at least 800 V. As referred to herein, “low voltage” means an electric component or circuit having a working voltage below that of “high voltage” in the same embodiment, for example up to about 100 V. Thus, for example, in a particular embodiment, “high voltage” batteries may be those operative at 200 V and above, and “low voltage” batteries may be those operative below 200 V.

Due to the large energy demands required to propel electric vehicles for long distances, high voltage battery systems included in electric vehicles may comprise thousands of individual cells. For some electric vehicle types and applications, such as commercial heavy-duty electric vehicles, the high voltage battery systems may comprise an even greater number of cells, for example, tens of thousands of individual cells. Recently, the introduction of new cell chemistries, improved cell designs, improved manufacturing processes, and active battery management strategies has greatly reduced the frequency and impact of battery cell failures. Nonetheless, the risk of thermal runaway-a critical failure where the temperature of a battery cell rises uncontrollably, posing risks of fire or explosion-still remains.

Common design goals for battery systems for electric vehicles include maximizing energy density (energy per unit volume) and maximizing specific energy (energy per unit mass). By maximizing energy density, more space is available to package other components or systems in the vehicle, leading to greater design flexibility and improved user experience. By maximizing specific energy, mass of the battery system, and therefore vehicle, can be reduced, increasing efficiency and range. The latter is especially important in the context of commercial electric vehicles, given the increased energy demands. The practical result of the aforementioned is that battery cells are commonly packaged closely together, exacerbating the effects of thermal runaway of an individual cell. In other words, the likelihood that thermal runaway is propagated between cells has increased.

Thermal runaway at a cell, block, module, pack, and/or system level can result from a number of issues, including: Overcharging: continuous charging beyond the battery's specified voltage limits can cause the formation of lithium metal on the anode, leading to internal short circuits and triggering thermal runaway; Overdischarging: discharging a battery below its recommended voltage can cause the formation of dendrites, which can penetrate the separator between electrodes, leading to internal short circuits and thermal runaway; External Short Circuit: accidental short circuits caused by damaged wiring, faulty connectors, or physical damage to the battery pack can cause rapid discharge, generating excessive heat and initiating thermal runaway; Internal Short Circuit: manufacturing defects, such as impurities or damage to the electrode coatings, can create internal short circuits within the battery cells, leading to localized heating and thermal runaway; Mechanical Stress: physical deformation or puncture of battery cells, either during manufacturing, installation, or operation, can damage internal components, leading to short circuits and thermal runaway; Aging and Degradation: gradual degradation of battery materials and electrolyte decomposition in certain cells over time can increase internal resistance, leading to increased heat generation during charging and discharging of the applicable cells, potentially leading to thermal runaway which can be propagated to adjacent cells; External Heating: exposure to external heat sources such as fire, excessive sunlight, or proximity to hot objects can raise the temperature of the cell or pack, initiating thermal runaway; Poor Cell Balancing: significant differences in cell voltage due to poor balancing can lead to overcharging or overdischarging of individual cells, increasing the risk of thermal runaway; and Chemical Contamination: contamination of electrolytes or electrode materials with impurities during manufacturing can lead to side reactions, gas evolution, and thermal instability, exacerbating the risk of thermal runaway.

In order to monitor cell parameters corresponding to a thermal runaway event, and other parameters indicative of battery health, modern electric vehicle battery systems are typically instrumented with one or more sensors at a cell, block, module, and/or pack level. Data measured by these sensors is periodically communicated to one or more electronic control units (ECUs) (for example, a battery management system (BMS)) on the vehicle to determine the battery's state of charge (SOC), state of health (SOH), state of power (SOP), and other measurements. However, this arrangement results in a number of shortcomings, particularly as it relates to the topic of thermal runaway detection.

First, given the number of cells, it is impractical to instrument every cell in the battery system as doing so would increase bill of material (BOM) cost, part count, system complexity, data burden, and processing burden. As such, many battery system manufacturers elect to instrument a subset of the cells. While this design avoids many of the drawbacks listed above, it also results in lower data resolution and limits understanding of behavior at the cell level. Moreover, conventional BMSs and other ECUs lack the ability to predict a thermal runaway event in advance. Instead, such events are often identified at the time of occurrence, limiting the availability of preventative or mitigative actions and increasing safety risks. Accordingly, systems and methods capable of early detection of thermal runaway events based on limited battery system data remain desirable.

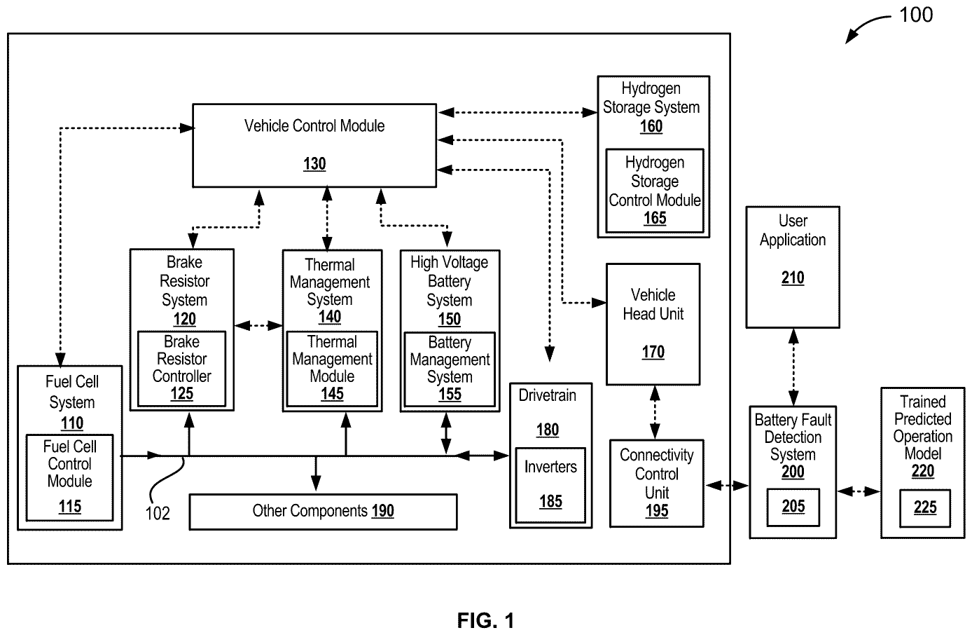

Accordingly, with reference to FIG. 1, a block diagram of an exemplary FCEV 100 is illustrated in accordance with various embodiments. In some embodiments, FCEV 100 comprises a commercial Class 8 FCEV; however, FCEV 100 may comprise any vehicle classification or application. Moreover, while discussed in relation to an FCEV, FCEV 100 is not limited in this regard and may comprise a BEV, hybrid, or other vehicle powertrain configuration containing a high voltage battery system. While not illustrated, FCEV 100 further comprises a chassis, cabin, one or more axles, one or more wheels, a suspension system, steering system, and other electrical, mechanical, and electromechanical systems as is conventional.

In various embodiments, FCEV 100 comprises a fuel cell system 110. Fuel cell system 110 may comprise one or more fuel cells capable of facilitating an electrochemical reaction to produce an electric current. For example, the one or more fuel cells may be proton-exchange membrane (PEM) fuel cells which may receive a fuel source (such as diatomic hydrogen gas) which may react with an oxidizing agent (such as oxygen) to generate electricity with heat and water as byproducts. The fuel cells may be electrically coupled in series and/or parallel to increase operating voltage and/or current and form one or more fuel cell stacks, which together form fuel cell system 110. In various embodiments, fuel cell system 110 may comprise fuel cells other than PEM fuel cells, for example, alkaline fuel cells, phosphoric acid fuel cells, molten carbonate fuel cells, solid oxide fuel cells, or any other suitable fuel cell type.

Fuel cell system 110 may be electrically coupled to a high voltage battery system 150 via a high voltage bus 102 in various embodiments. More specifically, fuel cell system 110 and high voltage battery system 150 (and other systems electrically coupled to high voltage bus 102) may be electrically coupled using a high voltage cable harness, for example. High voltage battery system 150 may comprise one or more rechargeable, or secondary, batteries configured to store electrical energy from an external power source (for example, a charging station), fuel cell system 110, and/or from a drivetrain 180 through regenerative braking. In various embodiments, high voltage battery system 150 comprises a lithium-ion battery, however, high voltage battery system 150 is not limited in this regard and may comprise other rechargeable battery types such as a lead-acid battery, nickel-cadmium battery, nickel-metal hydride battery, lithium iron sulfate battery, lithium iron phosphate battery, lithium sulfur battery, solid state battery, flow battery, or any other suitable battery.

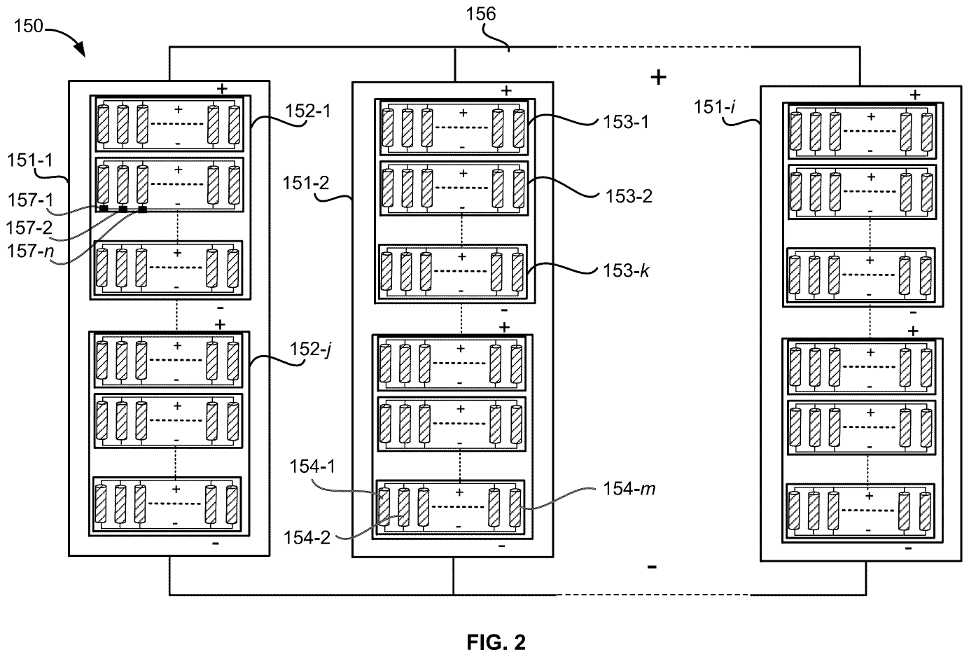

With momentary reference to FIG. 2, an exemplary high voltage battery system 150 is illustrated in more detail, in accordance with various embodiments. In various embodiments, high voltage battery system 150 comprises one or more battery packs (151-1, 151-2, to 151-i) comprising one or more battery modules (152-1, 152-2, to 152-j) comprising one or more battery blocks (153-1, 153-2, to 153-k) comprising one or more battery cells (154-1, 154-2, to 154-m), where i, j, k, m are each any positive integer, and may be the same or may differ from one another. In other words, battery cells 154 may be electrically coupled together via an electrical connection 156 to form battery blocks 153, which may be electrically coupled together via electrical connection 156 to form battery modules 152, which may be electrically coupled together via electrical connection 156 to form battery packs 151. In various embodiments, electrical connection 156 comprises a conductive material (for example, copper) capable of safely passing a required amount of electric current, for example, a wire assembly, cable assembly, busbar assembly, or a combination thereof.

In various embodiments, battery cells 154 comprise cylindrical cells, however, battery cells 154 are not limited in this regard and may comprise any suitable form factor, including prismatic cells, pouch cells, or a combination of any of the above. As illustrated in FIG. 2, battery cells 154 are electrically coupled in parallel, battery blocks 153 are electrically coupled in series, battery modules 152 are electrically coupled in series, and battery packs 151 are electrically coupled in parallel to form high voltage battery system 150. It should be appreciated, however, that any combination of series and parallel connections to achieve any desired battery system voltage and/or current configuration or capability is contemplated herein. For example, in one exemplary embodiment, a battery pack 151 comprises 15 battery modules 152 in series, each comprised of 12 battery blocks 153 in series; each battery block 153 comprises 24 battery cells 154 in parallel. Moreover, it will be appreciated that when a battery block 153 comprises battery cells 154 in parallel, such battery block 153 has one voltage value across its terminals due to the internal parallel configuration.

High voltage battery system 150 further comprises one or more sensors (157-1, 157-2, to 157-n) in various embodiments. Sensors 157 may comprise any suitable sensor type or combination of sensors, for example, temperature sensors, current sensors, voltage sensors, pressure sensors, humidity sensors, water detection sensors, hydrogen sensors, inertial sensors, magnetometers, gas sensors, microelectromechanical systems (MEMS) based sensors, or the like. In various embodiments, sensors 157 are coupled directly or indirectly to one or more of battery cells 154, battery blocks 153, battery modules 152, battery packs 151, or a combination thereof. In some embodiments, high voltage battery system 150 (or packs 151) may comprise fewer sensors 157 than battery cells 154, battery blocks 153, and/or battery modules 152. In other words, in some embodiments, data may be obtained from a subset or partial number of instrumented battery cells 154, battery blocks 153, and/or battery modules 152 so as to reduce costs, part count, data collection, storage, and/or processing burden. Moreover, the type, number, placement, configuration and other aspects of sensors 157 may be the same or may differ between battery cells 154, battery blocks 153, battery modules 152, and/or battery packs 151.

In various embodiments, sensors 157 measure relevant battery system data and transmit the measured data to one or more system-level or vehicle level ECUs. In some embodiments, sensors 157 transmit measured battery system data to a battery management system (BMS) 155, a master battery management system (MBMS) contained in a vehicle control module 130, or other ECU. As such, in various embodiments, sensors 157 are communicatively coupled to one or more ECUs via local interconnect network (LIN) protocol or controller area network (CAN) bus standard, for example. In various embodiments, sensors 157 are configured to measure and/or transmit relevant battery system data at an interval of 1 millisecond (ms), 10 ms, 100 ms, Is, 10s, 100s, or any other desired interval. In various embodiments, relevant battery system data may include one or more of cell, block, module, and/or pack voltage, current, temperature, capacity, impedance, charging/discharging rate, SOC, SOH, SOP, or other relevant data. In some embodiments, so as to limit storage, transmission, and/or processing burden, sensors 157 may be configured to measure the minimum, maximum, mean, median, mode, or other statistical measure of any of the above battery system data. Alternatively, the one or more ECUs (for example, BMS 155) may be configured to calculate the same based on the complete dataset measured by sensors 157.

Returning to FIG. 1, high voltage battery system 150 may be configured to release stored electrical energy to power one or more electric motors included in drivetrain 180. More specifically, high voltage battery assembly 150 may be configured to provide direct current to one or more inverters 185 in drivetrain 180, which may be configured to convert direct current to three-phase alternating current to power the electric motors. Electrical energy captured by the electric motors via regenerative braking may also be returned to high voltage bus 102 via inverters 185.

In various embodiments, FCEV 100 further comprises a brake resistor system 120. As FCEV 100 decelerates, the electric motors in drivetrain 180 function as generators and convert kinetic energy to electrical energy to charge high voltage battery system 150. When high voltage battery system 150 is fully charged or unable to accept a certain amount of electrical energy generated through regenerative braking, some of that electrical energy may be dissipated as heat by brake resistor system 120. As such, brake resistor system 120 is electrically coupled to and configured to receive electrical energy from high voltage bus 102.

FCEV 100 further comprises a thermal management system 140 in various embodiments. Thermal management system 140 comprises multiple thermal management loops devoted to thermally condition (i.e., ensure that the thermally managed component or system operates in a desired temperature range) one or more vehicle systems, including fuel cell system 110, brake resistor system 120, high voltage battery system 150, drivetrain 180, and other components and systems such as power electronics, and the heating, ventilation, and air conditioning (HVAC) system. As such, thermal management system 140 may comprise one or more coolant lines, radiators, fans, expansion tanks, bypass values, heat exchangers, pumps, and other components. Additionally, thermal management system 140 is electrically coupled to and configured to receive electrical energy from high voltage bus 102.

FCEV 100 further comprises a hydrogen storage system 160 in various embodiments. Hydrogen storage system 160 may comprise one or more hydrogen storage tanks configured to store gaseous or liquid hydrogen fuel. In various embodiments, the hydrogen storage tanks are fluidly coupled to a fuel plumbing system, one or more vent stacks, a manifold, a pressure regulator, fuel cell system 110, and other components. Hydrogen storage system 160 may be configured to selectively deliver hydrogen fuel to fuel cell system 110, thereby enabling fuel cell system 110 to generate and provide electrical energy to high voltage battery system 150 and other systems electrically coupled to high voltage bus 102.

FCEV 100 further comprises other components 190 in various embodiments. Other components 190 may include other components electrically coupled to high voltage bus 102 not previously mentioned, for example, DC/DC converters, compressors, fans, power distribution units (PDUs), and other components.

As discussed above, FCEV 100 further comprises one more ECUs. FCEV 100 may comprise vehicle control module 130, which may be responsible for the high-level control logic for FCEV 100. More specifically, vehicle control module 130 may be responsible for the interoperability of various vehicle systems including fuel cell system 110, brake resistor system 120, thermal management system 140, high voltage battery system 150, and hydrogen storage system 160. In some embodiments, vehicle control module 130 may be configured to manage FCEV 100's energy flow, monitor FCEV 100's vehicle dynamics and safety systems, enable general vehicle functions, and be responsible for FCEV 100's fault response strategy and state selection. As such, in various embodiments, vehicle control module 130 may be in wired, wireless, and/or logical communication with additional ECUs, for example, a fuel cell control module 115 (responsible for, in part, fuel cell system 110 power output), brake resistor controller 125 (responsible for, in part, the amount of power dissipation by brake resistor system 120), thermal management module 145 (responsible for, in part, thermal component control), pack-level BMS 155 (responsible for, in part, control and monitoring of high voltage battery system 150), inverters 185 (responsible for, in part, power control to and from electric motors), hydrogen storage control module 165 (responsible for, in part, delivery of hydrogen fuel to fuel cell system 110), vehicle head unit 170, and other ECUs.

Vehicle head unit 170, also known as the infotainment system, may comprise one or more display screens, buttons, controls, and other hardware configured to permit the operator to interface with and/or control many of FCEV 100's operator functions, for example, temperature control, navigation, exterior cameras, lights, audio settings, and other functions. Vehicle head unit 170 may further be configured to display or output relevant operation information, safety information, fault information, system information, and the like to the operator through visual, audio, haptic, or other feedback mechanisms.

In various embodiments, FCEV 100 may further comprise a connectivity control unit 195 in wired, wireless, and/or logical communication with vehicle head unit 170. Connectivity control unit 195 may be configured to receive and store data obtained from vehicle head unit 170, for example, and transmit the same (e.g., over a wired, wireless, or other suitable communicative connection) over a network to a battery fault detection system 200. More specifically, in various embodiments, connectivity control unit 195 may be configured to transmit battery system data measured by high voltage battery system 150 sensors 157, which may be communicated by battery management system 155 to vehicle control module 130 to vehicle head unit 170. In turn, battery fault detection system 200 may be configured to process the battery system data to determine whether a thermal runaway fault is present (i.e., whether conditions are present indicating a thermal runaway event is likely to occur in the near term). It will be appreciated that, in various exemplary embodiments discussed herein and as shown in FIG. 1, battery fault detection system 200 is remote from FCEV 100; however, in other exemplary embodiments battery fault detection system 200 is operative on and/or comprises components located on FCEV 100. Moreover, battery fault detection system 200 can comprise on-vehicle and off-vehicle components, as desired.

In various embodiments, battery fault detection system 200 may comprise any suitable combination of hardware, software, and/or database components. For example, battery fault detection system 200 may comprise one or more network environments, servers, computer-based systems, processors, databases, and/or the like. Battery fault detection system 200 may comprise at least one computing device in the form of a computer or processor, or a set of computers/processors, although other types of computing units or systems may be used, such as, for example, a server, web server, pooled servers, or the like. Battery fault detection system 200 may also include one or more data centers, cloud storages, or the like and may include software, such as APIs, SDKs, etc. configured to retrieve and write data to a user application 210 and/or a trained predicted operation model 220. In various embodiments, battery fault detection system 200 may include one or more processors and/or one or more tangible, non-transitory memories and be capable of implementing logic. The processor may be configured to implement various logical operations in response to execution of instructions. For example, instructions may be stored on a non-transitory, tangible, computer-readable storage medium 205 and may, in response to execution by battery fault detection system 200, cause battery fault detection system 200 to perform operations related to the identification of a battery thermal runaway fault associated with high voltage battery system 150.

In various embodiments, battery fault detection system 200 may comprise a cloud-based high performance computing network. In this regard, battery fault detection system 200 may include a high-performance computing cluster configured to utilize parallel computing. Stated differently, battery fault detection system 200 may comprise a plurality of high-performance computing resources arranged in a distributed array for parallel computing—e.g., battery fault detection system 200 may comprise a plurality of compute nodes arranged in an array and configured for parallel processing of massive amounts of data. It will be appreciated that battery fault detection system 200 may utilize one or more processors, processor systems, blades, racks, and/or the like of any appropriate type/configuration and/or any appropriate processing architecture. For example, battery fault detection system 200 may utilize one or more of x86 architecture compatible processors, Nvidia GB200 superchip systems and/or H100 GPUS, Intel Xeon processors, AMD Epyc server processors, and/or ARM-based processors such as Ampere Altra processors, ARM Neoverse N2 processors, Google Axion processors, and the like. Moreover, battery fault detection system 200 may comprise an entirely virtualized system operative across a diverse array of computing resources that may be located in multiple locations.

In various embodiments, battery fault detection system 200 may be in wired, wireless, and/or logical communication with trained predicted operation model 220. Similar to battery fault detection system 200, trained predicted operation model 220 may comprise any suitable combination of hardware, software, database components, cloud-based high performance computing network(s) or the like. In various embodiments, battery fault detection system 200 may be configured to transmit data obtained from FCEV 100 to trained predicted operation model 220, and trained predicted operation model 220 may be configured to output predicted behavior based on the model. As with battery fault detection system 200, trained predicted operation model 220 may be remote from FCEV 100; alternatively, trained predicted operation model 220 may be operative on and/or comprise components of FCEV 100.

In various embodiments, trained predicted operation model 220 may comprise a battery operation database 225. Battery operation database 225 comprises a suitable data structure, such as, for example, a database (including a relational, hierarchical, graphical, blockchain, or object-oriented structure, or other database configuration) or a flat file structure. Battery operation database 225 may be configured to store and maintain historical operational data associated with high voltage battery system 150. For example, battery operation database 225 may store and maintain models comprising historical operational data for each battery pack 151 in high voltage battery system 150, including one or more of cell, block, module, and/or pack voltage, current, temperature, capacity, impedance, charging/discharging rate, SOC, SOH, SOP, or other relevant data.

In some embodiments, so as to limit storage, transmission, and processing burden, and the need for a substantial number of sensors in battery packs 151, the operational data may be the minimum, maximum, mean, median, mode or other statistical measure of any of the above data and/or may be based on measurements associated with a group of cells, for example, a block, a plurality of blocks, a module, or a plurality of modules. In some exemplary embodiments, the operational data may comprise inputs of pack voltage (i.e., total voltage of each battery pack 151), average cell voltage (i.e., average cell voltage among a plurality of cell, block, and/or module voltages for each battery pack 151), minimum cell voltage (i.e., minimum cell voltage among a plurality of cell, block, and/or module voltages for each battery pack 151), maximum cell voltage (i.e., maximum cell voltage among a plurality of cell, block, and/or module voltages for each battery pack 151), pack SOC (i.e., average charge level for each battery pack 151), pack current (i.e., total current passing through each battery pack 151), and average or maximum pack temperature (i.e., average or maximum temperature among a plurality of cell, block, and/or module temperatures for each battery pack 151). In some exemplary embodiments, battery operation database 225 may include a plurality of the inputs above, for example, pack voltage, average cell voltage, etc. at each operational interval of FCEV 100. Stated otherwise, sensors 157 may be configured to measure the inputs above at an interval of Ims, 10 ms, 100 ms, 1s, 10s, 100s, or any other desired interval and these values may be stored in battery operation database 225. In some exemplary embodiments, the operational data, or inputs, may be measured and stored in battery operation database 225 over an operational window of FCEV 100, for example, 2 hours of operation, 4 hours of operation, 8 hours of operation, or any other desired operation window.

In various embodiments, data from battery operation database 225 may be used to create, train, and refine trained predicted operation model 220. Once trained predicted operation model 220 is trained, additional operational data, or inputs, discussed above may be entered into trained predicted operation model 220 and trained predicted operation model 220 may be configured to output one or more outputs that correspond with expected operation of high voltage battery system 150, and in particular, packs 151. In various embodiments, the outputs from trained predicted operation model 220 may be any of the inputs discussed above. In some embodiments, the outputs may be minimum cell voltage (i.e., minimum cell voltage among a plurality of cell, block, and/or module voltages for each battery pack 151) or maximum cell voltage (i.e., maximum cell voltage among a plurality of cell, block, and/or module voltages for each battery pack 151). In turn, these outputs can be compared to real world operational data obtained from FCEV 100 and high voltage battery system 150 to determine the presence of any abnormalities corresponding to an increased risk of a thermal runaway event.

In various embodiments, trained predicted operation model 220 may be of a deep learning structure or configuration—e.g., a convolutional neural network (CNN), recurrent neural network (RNN), long short-term memory (LSTM) network, physics-informed neural network (PINN), gated recurrent unit (GRU), or other suitable deep learning structure. In some embodiments, trained predicted operation model 220 may comprise a probabilistic or statistical model, for example, a Gaussian process. In some embodiments, trained predicted operation model 220 comprises an evolutionary computing structure, for example, a genetic algorithm (GA), genetic programming (GP), evolutionary strategies(ES), or differential evolution (DE).

In various embodiments, such as where trained predicted operation model 220 comprises a CNN, trained predicted operation model 220 may comprise multiple layers. For example, in certain embodiments, trained predicted operation model 220 may comprise an input layer, a convolutional layer, a pooling layer, a flattening layer, a fully connected layer, and an output layer. In various embodiments, the inputs identified above may be input into the input layer. In some embodiments, the input data may be converted into an image format, an array, a series of arrays (one for each input), or other structure capable of enabling spatial and/or time series feature or pattern recognition prior to input into the input layer. Following this, the convolutional layer may be used to extract features or patterns between adjacent points in the image, array, or series of arrays. In various embodiments, the pooling layers may be configured to decrease the size of the convoluted feature or pattern map. The flattening layer may be configured to reduce the dimensionality of the data and prepare the data for input into the fully connected layer. The fully connected layer may be configured to produce one or more output predictions, for example, predicted maximum and/or minimum cell voltage, and the final output may be selected by the output layer. It will be appreciated that in the foregoing, a layer may comprise or be configured with one or more sub-layers.

Outputs generated by trained predicted operation model 220 may be returned to battery fault detection system 200 and stored on storage medium 205 for later reference. More specifically, as will be discussed in further detail below, battery fault detection system 200 may be configured to compare real (or actual) operational data associated with high voltage battery system 150, which may also be stored on storage medium 205 or other storage medium, with the outputs or predicted data from trained prediction operation model 220. It will be appreciated that, in many embodiments, because FCEV 100 is not an internal combustion vehicle FCEV 100 or components thereof are “operating” even when FCEV 100 is parked, stationary, or otherwise appears to be “off.” In turn, one or more algorithms may be used to identify the presence of anomalies signaling an increased risk of thermal runaway events in one or more battery packs 151. In response to a fault being identified by battery fault detection system 200, various messages may be generated and/or actions may be taken. For example, battery fault detection system 200 may be configured to transmit the fault findings to user application 210. In some embodiments, user application 210 may comprise a downloadable or non-downloadable, web-based telematics, fleet management, service, supplier, manufacturing, OEM, emergency response, or other suitable software. In some embodiments, user application 210 may be an application for use on a tablet, cellular phone, laptop computer, or other apparatus. In some embodiments, user application 210 may be an application existing on or in logical communication with one or more of the ECUs of FCEV 100, for example, vehicle head unit 170.

In various exemplary embodiments, in response to a fault being identified by battery fault detection system 200, a battery pack 151 associated with the fault may be disconnected. Battery pack 151 may be disconnected via operation of any suitable components (e.g., switches, relays, fuses, and/or the like). Disconnection of battery pack 151 may be performed under the control of any suitable components, for example vehicle control module 130, battery management system 155, and/or the like. Disconnection of battery pack 151 may be performed at the direction and/or under the control of components located on FCEV 100, located remote from FCEV 100 and in communicative connection therewith, or a combination of the foregoing.

Once a faulted battery pack 151 has been disconnected, it may desirably be at least partially discharged, for example in order to reduce the likelihood of thermal runaway or other cascading faults or damage. Discharging of faulted battery pack 151 may be performed by any suitable techniques or components. For example, faulted battery pack 151 may be discharged by using faulted battery pack 151 to charge one or more other battery packs 151 in high voltage battery system 150. Alternatively, faulted battery pack 151 may be discharged by drawing current therefrom to operate one or more fans, pumps, or other electromechanical components of FCEV 100. Moreover, faulted battery pack 151 may be discharged by routing current therefrom to a brake resistor of FCEV 100. Yet further, faulted battery pack 151 may be discharged by drawing current therefrom through a battery discharge resistor; in one particular embodiment, a 60-ohm resistor and 0.1C current draw rate may be utilized to draw about 100A through a battery discharge resistor and generate around 6 kW of heat during discharge. More generally, in various exemplary embodiments a battery discharge resistor may be configured with a resistance of between about 10 ohms and about 100 ohms in order to draw a current up to about 0.1C, which may be between about 1-10 amps from a 100 amp-hour battery pack 151 such that between about 1 kW and about 10 KW of heat are generated during discharge. It will be appreciated that 0.1C is a fixed rate, but the current will decrease during the discharge process due to the lower open circuit voltage. It is preferable to discharge battery pack 151 using a rate less than or equal to 0.1C; in general, lower rates of discharge are correlated with greater safety.

Selection of discharge strategy may be based on various factors, such as state of charge of other battery packs 151, ambient temperature around FCEV 100, thermal condition of a brake resistor, availability of electromechanical components to accept current from faulted battery pack 151, and/or the like. Multiple discharge approaches may be pursued simultaneously and/or in a selected order; for example, faulted battery pack 151 may be used to charge other battery pack(s) 151 until the other battery pack(s) 151 reach a threshold level of charge; thereafter, current from faulted battery pack 151 may be dumped into a brake resistor until faulted battery pack 151 is discharged to a desired level.

Faulted battery pack 151 may be discharged to any suitable level, for example down to 30%, 20%, 10%, 5%, 2%, 1% or 0% of rated capacity. Moreover, faulted battery pack 151 may be discharged until the voltage of faulted battery pack 151 declines to at least a discharged voltage threshold. Additionally, faulted battery pack 151 may be discharged until a particular amount of current has been drawn from faulted battery pack 151 for a particular amount of time.

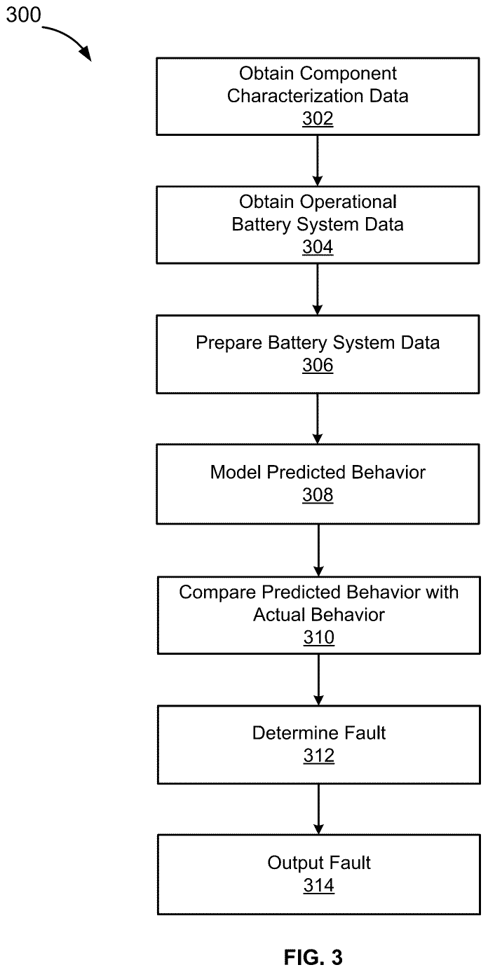

With reference now to FIG. 3, a method 300 for identifying a battery thermal runaway fault is illustrated, in accordance with various embodiments. In addition to the discussion below, method 300 may comprise or utilize some or all of the components, systems, and methods discussed above in relation to FIGS. 1 and 2. Further, the principles discussed below may apply to real (or actual) operational data associated with high voltage battery system 150 or predicted or modeled operational data associated with high voltage battery system 150. Moreover, method 300 may be used in connection with a high voltage battery system on an FCEV, BEV, or any application including a high voltage battery system equipped with instrumentation for data collection. In general, principles of the present disclosure contemplate that because each battery pack 151 (and/or battery module 152 or battery block 153) may perform differently, it is desirable to (i) characterize each battery pack 151, (ii) measure/monitor operation thereof, (iii) utilize a prediction model for each battery pack 151 based on the characterization and measurements, and (iv) compare measured data for each battery pack 151 to predicted data to determine battery health and take appropriate actions.

Method 300 begins at step 302. As an initial step, characterization data for one or more components of high voltage battery system 150 is obtained. This can include data associated with initial manufacture, testing, evaluation, and/or characterization of one or more battery cells 154, battery blocks 153, battery modules 152, and or battery packs 151 in high voltage battery system 150. Additionally, this can include data associated with testing, evaluation, and/or characterization of FCEV 100 during manufacture and/or upon initial completion of the vehicle. Use of this data by battery fault detection system 200 allows for more accurate fault detection by accounting for differences that may arise due to manufacturing variations, material imperfections, component manufacturing date differences, and/or the like. The characterization data may be provided by a component manufacturer. Alternatively, components of high voltage battery system 150 and/or other components of FCEV 100 may be tested, measured, or evaluated in order to obtain characterization data.

At step 304, battery fault detection system 200 receives operational battery system data. More specifically, battery fault detection system 200 may receive real (or actual) operational data associated with high voltage battery system 150 of FCEV 100. For example, battery fault detection system 200 may receive and store historical operational data for each battery pack 151 in high voltage battery system 150, including one or more of cell, block, module, and/or pack voltage, current, temperature, capacity, impedance, charging/discharging rate, SOC, SOH, SOP, or other relevant data.

In some embodiments, so as to limit storage, transmission, and processing burden, and the need for a substantial number of sensors in battery packs 151, the operational data may be the minimum, maximum, mean, median, mode or other statistical measure of any of the above data and/or may be based on measurements associated with a group of battery cells 154, for example, a block, a plurality of blocks, a module, or a plurality of modules. In some exemplary embodiments, the operational data may comprise pack voltage (i.e., total voltage of each battery pack 151), average cell voltage (i.e., average cell voltage among a plurality of cell, block, and/or module voltages for each battery pack 151), minimum cell voltage (i.e., minimum cell voltage among a plurality of cell, block, and/or module voltages for each battery pack 151), maximum cell voltage (i.e., maximum cell voltage among a plurality of cell, block, and/or module voltages for each battery pack 151), pack SOC (i.e., average charge level for each battery pack 151), pack SOH (i.e., average health metric for each battery pack 151), pack current (i.e., total current passing through each battery pack 151), and average or maximum pack temperature (i.e., average or maximum temperature among a plurality of cell, block, and/or module temperatures for each battery pack 151). In some exemplary embodiments, the historical operational data may include a plurality of data points, for example, pack voltage, average cell voltage, etc. at each operational interval of FCEV 100. Stated otherwise, sensors 157 may be configured to measure the inputs above at an interval of Ims, 10 ms, 100 ms, 1s, 10s, 100s, or any other desired interval. In some exemplary embodiments, the operational data may be measured over an operational window of FCEV 100, for example, 2 hours of operation, 4 hours of operation, 8 hours of operation, operation from the previous day, or any other desired operation window. In various embodiments, battery fault detection system 200 may receive the historical operational data from FCEV 100 directly or indirectly through connectivity control unit 195, vehicle head unit 170, and/or vehicle control module 130. In some embodiments, the historical operational data may be stored in one or more arrays, matrices, or other suitable data structure(s) in storage medium 205 for later comparison.

At step 306, the battery system data may be prepared for modeling by trained predicted operation model 220. The battery system data may be prepared by battery fault detection system 200. In some embodiments, step 306 may comprise indexing the data. For example, rather than receiving data at a given measured interval and/or window from sensors 157, raw data may be indexed into minute, hour, day, shift, or other suitable timeframe capable of differentiating one data set from another. In some embodiments, the data may be indexed for an individual vehicle. In other embodiments, data may be indexed for a plurality of vehicles, for example, vehicles associated with a given fleet, use case, model year, or other shared feature. In some embodiments, step 306 may comprise applying a data smoothing technique to the data, for example, applying and/or identifying a simple moving average (SMA), weighted moving average (WMA), exponential moving average (EMA), exponential weighted moving average (EWMA), Kalman filter or other suitable technique. In some embodiments, step 306 may comprise data scaling, stacking, concatenation, or other data organization or processing technique. For example, in some embodiments, like data (e.g., voltage data, current data, temperature data, etc.) may be concatenated into a single array, matrix, or other data structure based on time (e.g., maximum voltage at each second; minimum voltage at each second, pack current at each second, and so forth).

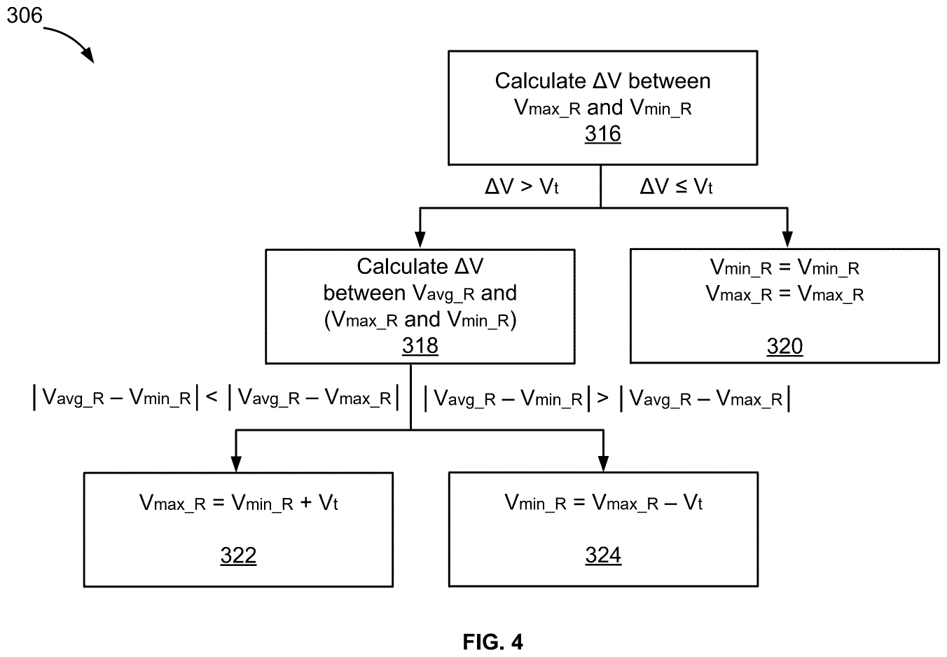

In some embodiments, step 306 may further comprise adjusting one or more of the data (or inputs). For example, with momentary reference to FIG. 4, step 306 may further comprise adjusting maximum or minimum voltage data, V_{max_R} and V_{min_R}, respectively. While discussed in relation to V_{max_R} and V_{min_R}, similar techniques may be used to adjust other data. In general, steps 316-324 may be configured to ensure good data (i.e., non-outlier data) are input into trained predicted operation model 220. Stated another way, the data may be processed to eliminate signal transients, noise, corrupted database entries, clearly erroneous or impossible sensor readings (e.g., an indication that voltage for a battery pack 151 is zero volts (shorted), or a voltage 5 times higher than the maximum voltage possible based on configuration of that battery pack 151, or the like), or other data that would impair the functioning or accuracy of the prediction model. As used herein, V_{max_R} refers to real (or actual) maximum voltage data, while Vmax p refers to modeled (or predicted) maximum voltage data. The same naming convention applies for average voltage data (e.g., V_{avg_R} and V_{avg_P}) and minimum voltage data (e.g., V_{min_R} and V_{min_P}).

At step 316, battery fault detection system 200 or other suitable processor may calculate a first voltage difference, or ΔV, between V_{max_R} and V_{min_R}. If the first voltage difference is less than or equal to a threshold, Vₜ, at step 320, V_{min_R} and V_{max_R} are maintained as their original values. Otherwise, if the first voltage difference is greater than the threshold, at step 318, a second voltage difference and a third voltage difference are calculated between an average voltage, V_{avg_R}, and V_{max_R} and V_{min_R}, respectively. If the absolute value of the second voltage difference is greater than the third voltage difference, at step 322, the threshold and V_{min_R} are added together and used as V_{max_R}. Otherwise, if the absolute value of the second voltage difference is less than the third voltage difference, at step 324, the threshold is subtracted from V_{max_R} and this value is used as V_{min_R}. In various embodiments, the threshold may be determined so as to avoid any false positives caused by values greater than the threshold, for example, 30 mV, 40 mV, 50 mV, 60 mV, or other suitable value. In such a way, outliers that may otherwise be unavailable as inputs into trained predicted operation model 220 may be salvaged and used in step 308. The indexed and/or adjusted data may then be sent from battery fault detection system 200 to trained predicted operation model 220 for processing by trained predicted operation model 220.

Returning to FIG. 3, at step 308, battery fault detection system operates (and/or is in communication with) a trained predicted operation model 220 that may model, or predict, an expected behavior of high voltage battery system 150 based on the historical battery system operational data (including characterization data for components of high voltage battery system 150). More specifically, in various embodiments, trained predicted operation model 220 may be configured to model (or predict) the minimum voltage V_{min_P} or the maximum voltage Vmax P for each battery pack 151 based on the historical operational data, or inputs, to trained predicted operation model 220. As discussed above, in some embodiments, trained predicted operation model 220 comprises a CNN, so trained predicted operation model 220 may be configured to output the predicted V_{max_p} based on an input of V_{min_R}, and vice versa. Moreover, trained predicted operation model 220 may be configured to consider other historical operational data, or inputs, useful in characterizing typical operation of high voltage battery system 150 (and battery packs 151) as discussed above, for example, temperature data, current data, or others. In various embodiments, trained predicted operation model 220 may be configured to output a Vmax P value, or alternatively, a V_{min_P} value, for each operational interval over an operational window (i.e., V_{max_P1} at time t₁, V_{max_P2} at time t₂ . . . . V_{max_Pn} at time tₙ for a window of time tₙ). In various embodiments, the outputs (e.g., V_{max_P} or V_{min_P}) may be stored as an array, matrix, or other suitable data structure in storage medium 225 and/or returned to battery fault detection system 200 and stored in storage medium 205.

At step 310, battery fault detection system 200 may be configured to compare the real (or actual) historical operational data (stored on storage medium 205) with the modeled (or predicted) operational data output by trained predicted operation model 220 (stored on storage medium 205, storage medium 225, or other suitable storage medium), and at step 312, battery fault detection system may be configured to determine the existence of a fault indicative of increased risk of thermal runaway.

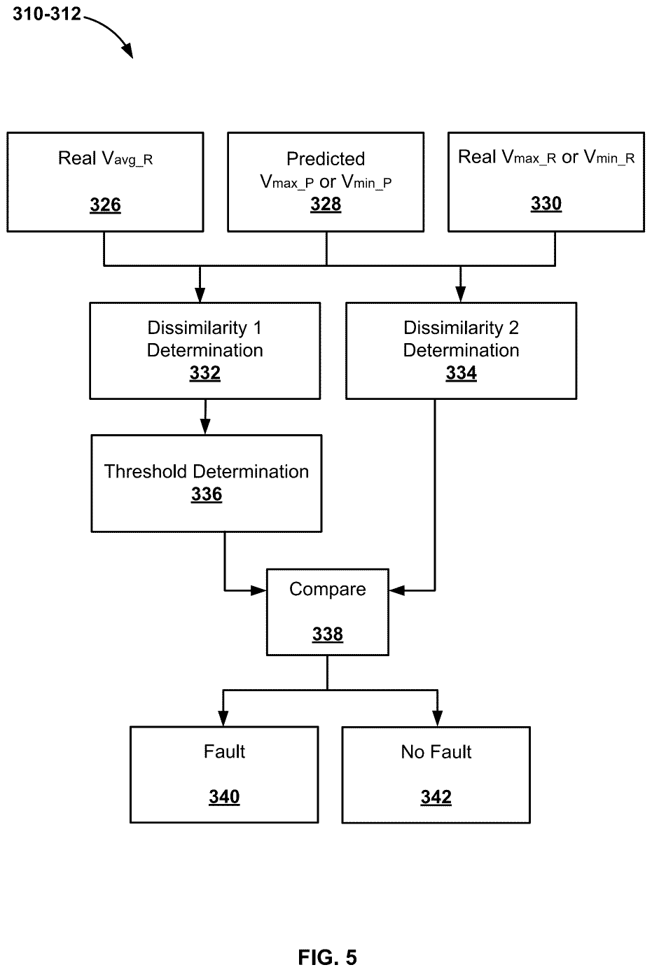

Further details of steps 310 and 312 are illustrated in FIG. 5. In various embodiments, battery fault detection system 200 may receive, or retrieve, real (or actual) average voltage data, V_{avg_R}, at step 326. Battery fault detection system 200 may further receive, or retrieve, modeled (or predicted) maximum voltage data, V_{max_P}, or alternatively, modeled (or predicted) minimum voltage data, V_{min_P}, at step 328. Battery fault detection system 200 may further receive, or retrieve, real (or actual) maximum voltage data, V_{max_R}, or alternatively, real (or actual) minimum voltage data, V_{min_R}, at step 330. In various embodiments, battery fault detection system 200 may receive, or retrieve, a plurality of each of the above, for example, one of each at a plurality of operational intervals.

At step 332, battery fault detection system 200 may determine a first dissimilarity between the data from step 326 and the data from step 328. For example, battery fault detection system 200 may plot the data from step 326 in a first curve and plot the data from step 328 in a second curve. A distance algorithm or metric, for example, a Fréchet algorithm, Hausdorff algorithm, t-test, p-test, 2-norm, infinity-norm, or other suitable metric may be used to determine the first dissimilarity between the first curve and the second curve, and the first dissimilarity may be saved as an array, matrix, plot, or other suitable structure or representation in storage medium 205 for later processing. Stated another way, in step 332 battery fault detection system 200 characterizes the relationship between measured average values and predicted values.

Similarly, at step 334, battery fault detection system 200 may determine a second dissimilarity between the data from step 328 and the data from step 330. For example, battery fault detection system 200 may plot the data from step 328 in the second curve and plot the data from step 330 in a third curve. A similar distance algorithm or metric, for example, the Fréchet algorithm, Hausdorff algorithm, t-test, p-test, 2-norm, infinity-norm, or other suitable metric may be used to determine the second dissimilarity between the second curve and the third curve, and the second dissimilarity may be saved as an array, matrix, plot, or other suitable structure or representation in storage medium 205 for later processing. Stated another way, in step 334 battery fault detection system 200 characterizes the relationship between measured instantaneous values and predicted instantaneous values.

It will be appreciated that when a battery pack 151 (and/or a battery module 152 and/or battery block 153) has a faulty condition (such as a failed, damaged, or failing battery cell 154 therein), the measured or real V_{min_R} will decrease, while the predicted or modeled V_{min_P} will maintain a certain value (and/or decrease at a slower rate). However, the second dissimilarity may not be set at a fixed level due at least in part to the variations inherent between battery cells 154, battery blocks 153, battery modules 152, and/or battery packs 151 (for example, variations in voltage, internal resistance, and/or the like). Said differently, if the component quality distribution or variation in a first battery pack 151 is greater than the component quality distribution or variation in a second battery pack 151, then the second dissimilarity for the first battery pack 151 may be greater than the second dissimilarity for the second battery pack 151. Thus, in various exemplary embodiments, the second dissimilarity is normalized (e.g., compare it based on battery component quality distribution) utilizing the first dissimilarity. In this manner, an appropriate threshold for determining the presence of a battery fault condition in each battery pack 151 can be implemented, taking into account the unique characteristics of each battery pack 151 and the components thereof.

At step 336, battery fault detection system 200 may determine a threshold based on the first dissimilarity. For example, in some embodiments, battery fault detection system 200 may be configured to apply the 3σ, or empirical rule, to the first dissimilarity by applying the following equation:

$$T = 1.3 \times {meanFD}_{1} + 3 \times {StdFD}_{1}$$

where T is the threshold and FD₁ is the first dissimilarity. Similar to the first dissimilarity and the second dissimilarity, the threshold may be saved as an array, matrix, plot, or other suitable structure or representation. Stated another way, in step 336 battery fault detection system 200 characterizes an amount (the threshold) by which the predicted values and the measured values may permissibly differ.

At step 338, battery fault detection system 200 may be configured to compare the threshold and the second dissimilarity, and at steps 340 and 342, determine the existence of a fault (or positive result), or lack of fault (or negative result), respectively. More specifically, in various embodiments, battery fault detection system 200 may be configured to compare the value of the second dissimilarity and the value of the threshold at each point in time and determine whether the value of the second dissimilarity exceeds the value of the threshold. If so, battery fault detection system 200 returns a positive result at the first point in time the second dissimilarity exceeds the threshold (step 340). Otherwise, battery fault detection system 200 continues to compare second dissimilarity values and threshold values throughout the duration of the window, and in the event battery fault detection system 200 determines there are no second dissimilarity values exceeding corresponding threshold values, returns a negative result for the window of operation being evaluated (step 342). In some embodiments, battery fault detection system 200 may be configured to plot the second dissimilarity values and threshold values on the same chart and return a positive result at the first point of intersection between the two curves.

In some embodiments, battery fault detection system 200 may require the second dissimilarity value to exceed the threshold value by a predetermined amount, for example, 10% greater than the threshold value, 20% greater than the threshold value, 30% greater than the threshold value, or other suitable amount before returning a positive result. In some embodiments, battery fault detection system 200 may require the second dissimilarity value exceed the threshold value for a predetermined time period, for example, two seconds (i.e., two pairs of second dissimilarity value and threshold value comparisons), five seconds (i.e., five pairs of second dissimilarity value and threshold value comparisons), ten seconds, or other predetermined time period before returning a positive result. In some embodiments, battery fault detection system 200 may compare the rate of change of the second dissimilarity and the threshold plots near a point of intersection of the two plots to determine whether to return a positive result. For example, battery fault detection system 200 may be configured to identify a point of intersection of the second dissimilarity and the threshold plots, calculate a difference in slope between the two plots, and compare the difference to a predetermined value. If the difference in slope between the two plots is greater than the predetermined value, battery fault detection system 200 returns a positive result. In some embodiments, battery fault detection system 200 may be configured to calculate the slope of the second dissimilarity and threshold plots over a time window comprising the point of intersection. In some embodiments, the time window may be +/− one second from the point of intersection, +/− two seconds from the point of intersection, +/− three seconds from the point of intersection, or other suitable window.

Returning to FIG. 3, at step 314, battery fault detection system 200 outputs its fault findings. In some embodiments, in response to a positive result, battery fault detection system 200 communicates the fault, time of fault, relevant ID (cell, block, module, pack, and/or vehicle), supporting data, and other useful information to user application 210 and/or FCEV 100, for example vehicle head unit 170. Vehicle head unit 170 may communicate the fault details to vehicle control module 130. In response to a positive result, various action(s) may be taken and/or further communications implemented, including but not limited to: analysis of the data and results to identify false positives, confirmation of the positive result, service notifications, safety notifications, and/or vehicle control strategies (e.g., immediate or scheduled high voltage shutdown, isolation of the faulted pack, limp home mode, etc.). In response to a negative result, the supporting data may be stored for future reference and/or returned to trained predicted operation model 220 for further training.

In various embodiments, method 300 may be performed for each battery pack 151 in high voltage battery system 150, enabling fault detection at the pack level. Method 300 (or a subset of steps thereof) may be performed repeatedly and/or regularly. For example, method 300 may be performed every 5 minutes, every 10 minutes, every 15 minutes, every 30 minutes, every hour, every 2 hours, every 4 hours, every 12 hours, or every 24 hours. Yet further, method 300 may be performed upon a triggering and/or threshold event, for example: the presence of FCEV 100 in ambient conditions exceeding a threshold temperature for a threshold period of time; sustained current draw from high voltage battery system 150 above a threshold current level for a threshold period of time; sustained charging of high voltage battery system 150 above a threshold current level for a threshold period of time; replacement or modification of a battery pack 151 in high voltage battery system 150; FCEV 100 being stationary for a threshold period of time; high voltage battery system 150 exceeding a threshold state of charge for a threshold period of time; a combination of a threshold state of charge and a threshold temperature for a threshold period of time; and/or the like or combinations thereof. Additionally, a subset of steps in method 300 may be performed at regular intervals; for example, battery packs 151 in high voltage battery system 150 may be regularly monitored by performing steps 310 and 312 (and if relevant, step 314) every second, every 2 seconds, every 5 seconds, every 10 seconds, every 30 seconds, every 60 seconds, every 5 minutes, every 15 minutes, every 30 minutes, or the like.

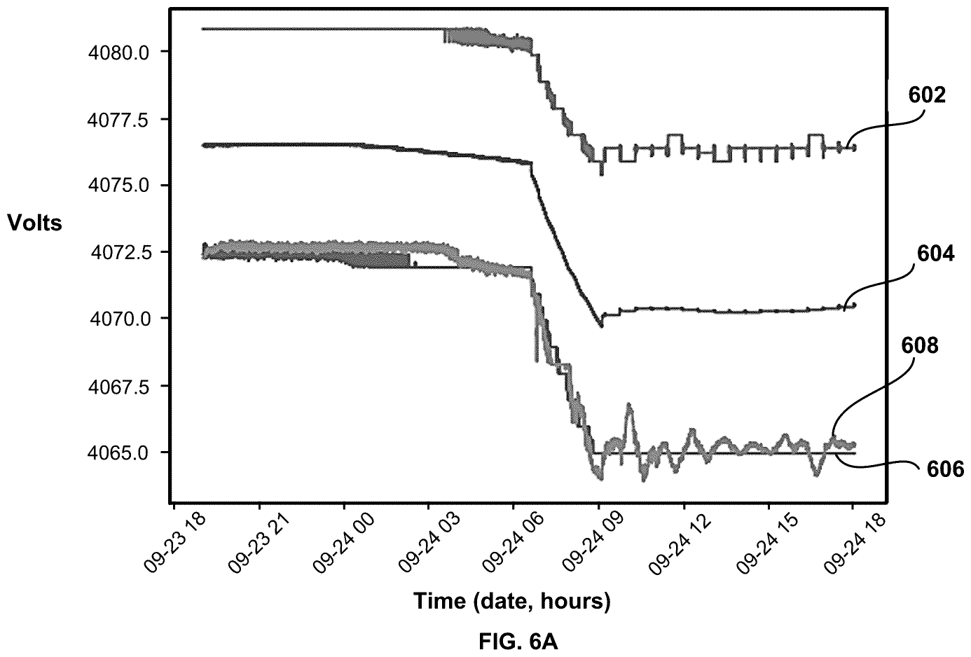

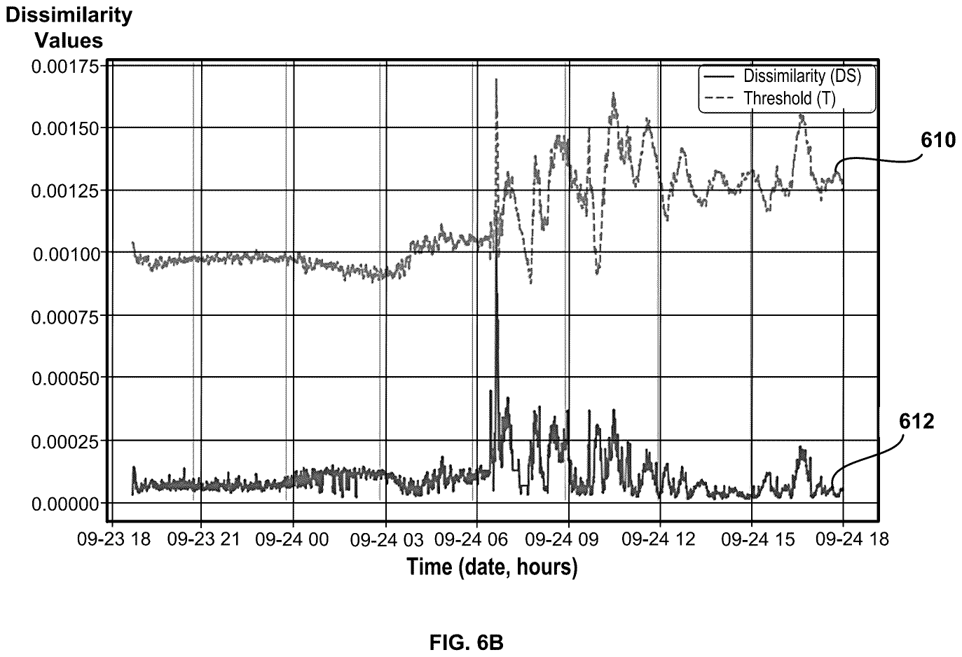

Referring now to FIGS. 6A and 6B, exemplary operational data associated with a healthy battery pack 151 is illustrated, in accordance with various embodiments. In some embodiments (where a battery block 153 is a parallel connection of battery cells 154), it will be appreciated that cell voltage may be determined by a sensor measuring the block voltage. In FIG. 6A, line 602 represents real (or actual) maximum cell voltage (i.e., V_{max_R}), line 604 represents real (or actual) average cell voltage (i.e., V_{avg_R}), line 606 represents real (or actual) minimum cell voltage (i.e., V_{min_R}), and line 608 represents modeled (or predicted) minimum cell voltage (i.e., V_{min_P}). As can be observed in this scenario, line 608 closely mirrors line 606. In other words, the modeled (or predicted) minimum cell voltage output from trained predicted operation model 220 closely tracks the real (or actual) minimum cell voltage measured by sensors 157 in the relevant battery pack 151. As such, a negative result (no fault) is expected and may be confirmed by the comparison between the second dissimilarity and threshold as discussed above. As can be seen from FIG. 6B, at no point does the second dissimilarity (line 612) exceed the threshold (line 610), confirming the negative result (no fault).

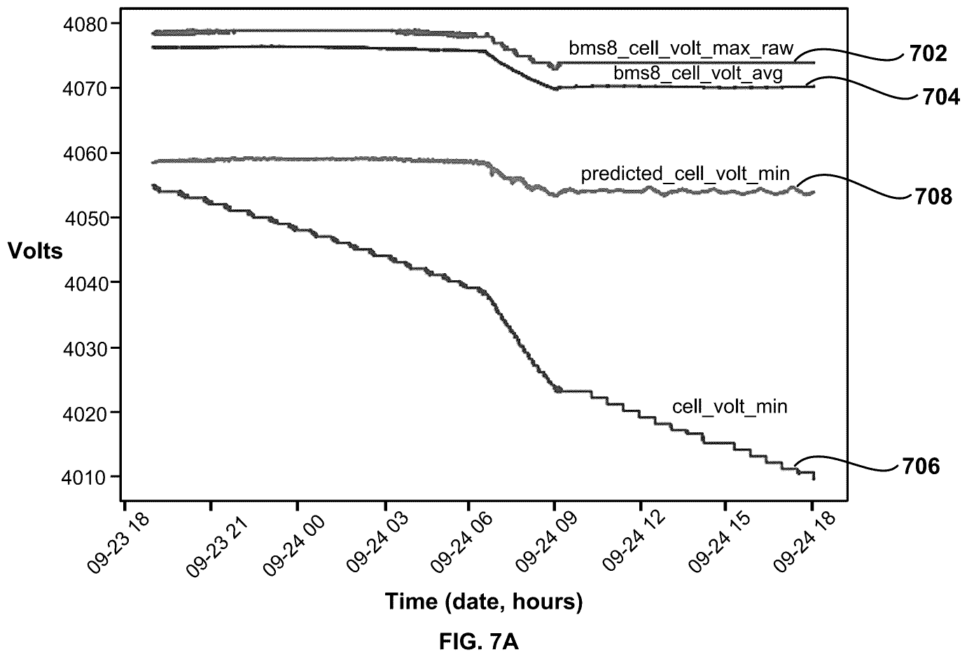

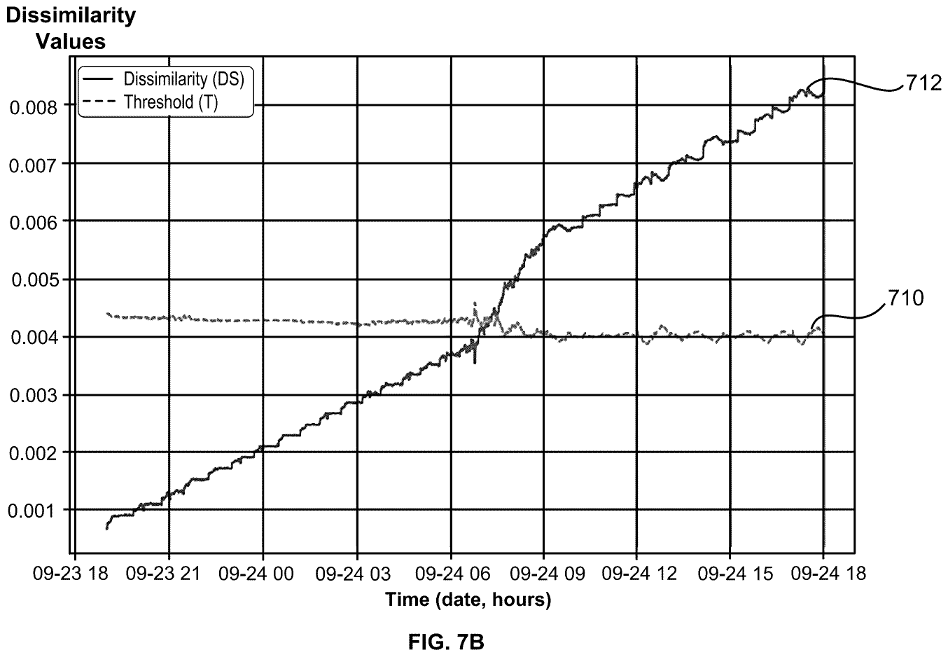

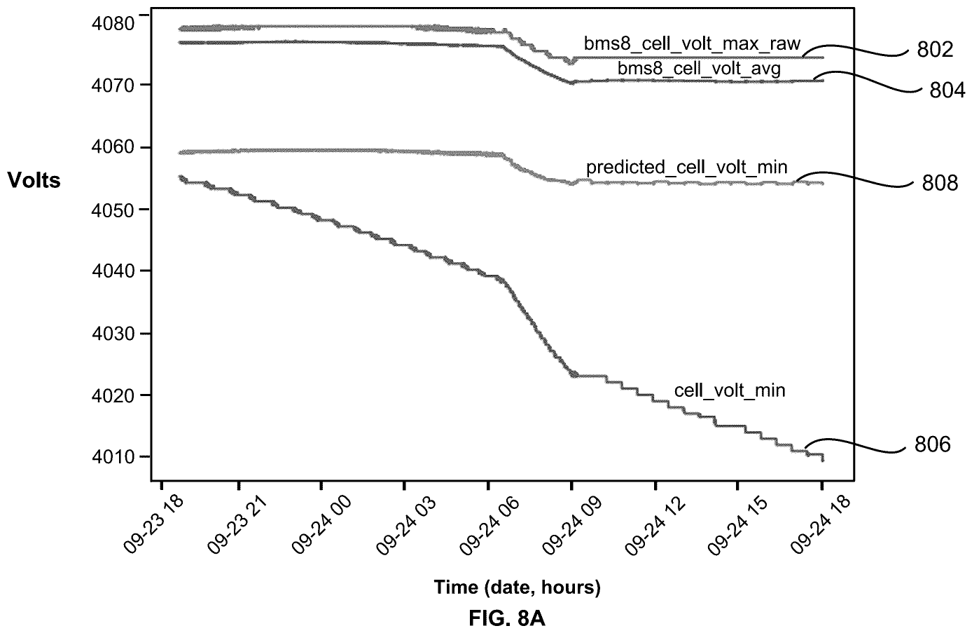

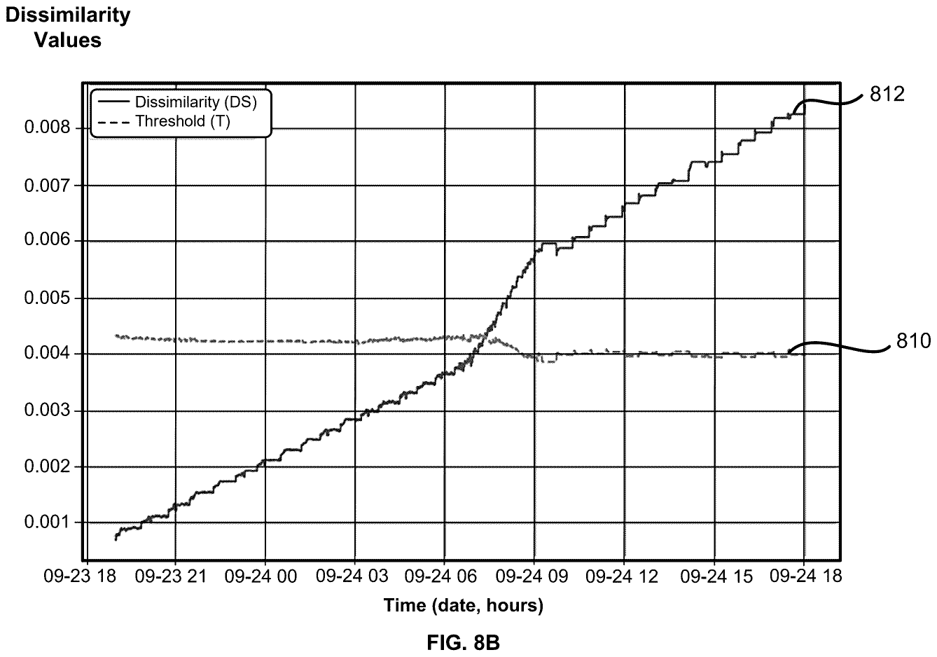

In contrast, and with reference to FIGS. 7A-8B, exemplary operational data associated with a faulted battery pack is illustrated, in accordance with various embodiments. FIGS. 7A and 7B illustrate operational data and outputs where trained predicted operation model 220 comprises a CNN deep learning algorithm, while FIGS. 8A and 8B illustrate operational data and outputs where trained predicted operation model 220 comprises a LSTM deep learning algorithm. As can be seen in FIGS. 7A and 8A, initially, the real (or actual) minimum cell voltage (i.e., V_{min_R}) represented by lines 706 and 806 closely match the modeled (or predicted) minimum cell voltage (i.e., V_{min_P}) represented by lines 708 and 808, respectively. However, as time progresses, the real (or actual) minimum cell voltage decreases at a much faster rate than the modeled (or predicted) minimum cell voltage. In other words, the real (or actual) minimum cell voltage is decreasing at a rate much greater than would be anticipated during normal operation. This is reflected in the comparison between the second dissimilarity and the threshold as illustrated in FIGS. 7B and 8B. As the real (or actual) minimum cell voltage and the modeled (or predicted) minimum cell voltage diverge, the second dissimilarity (lines 712 and 812) and the threshold (lines 710 and 810) converge until they eventually intersect and battery fault detection system 200 returns a positive result (fault) at the point of intersection.

Principles of the present disclosure enable early detection of high voltage battery system (or pack) faults related to heightened thermal runaway risk, thereby enabling appropriate response strategies prior to the thermal runaway event. In some embodiments, the fault may be identified as much as 1 hour, 2 hours, 6 hours, 12 hours, 24 hours, or even as much as 48 hours in advance of the thermal runaway event. Moreover, principles of the present disclosure are able to accomplish the above objectives using limited data and instrumentation, thereby decreasing system complexity, cost, storage and processing burden. Additionally, it will be appreciated that principles of the present disclosure improve the operation of computing systems by reducing network traffic, and decreasing the amount of data utilized for effective detection and management of thermal runaway conditions. Yet further, principles of the present disclosure also enable improvements and/or preservation of other systems, for example by preventing fires and consequent damage or destruction of batteries, vehicles, cargo, buildings, and/or the like.

Principles of the present disclosure may be compatible with and/or used in connection with principles set forth in the following: U.S. Ser. No. 19/045,335, published as U.S. Patent Application Publication No. 2025-0249852 entitled “Thermal Component Prioritization Control Logic and Methods;” and U.S. Pat. No. 12,291,112 entitled “High Voltage Battery Conditioning For Battery Electric Vehicle.” The disclosure of each of the foregoing applications is incorporated herein by reference in its entirety, including but not limited to those portions that specifically appear herein, but except for any subject matter disclaimers or disavowals, and except to the extent that the incorporated material is inconsistent with the express disclosure herein, in which case the language in this disclosure shall control.

Computer programs (also referred to as computer control logic) are stored in main memory and/or secondary memory. Computer programs may also be received via communications interface. These computer program instructions may be loaded onto a general-purpose computer, special purpose computer, controller, or other programmable data processing apparatus to produce a machine, such that the instructions that execute on the computer or other programmable data processing apparatus create means for implementing the functions specified in the flowchart block or blocks. These computer program instructions may also be stored in a computer-readable memory that can direct a computer, controller, or other programmable data processing apparatus to function in a particular manner, such that the instructions stored in the computer-readable memory produce an article of manufacture including instruction means which implement the function specified in the flowchart block or blocks. The computer program instructions may also be loaded onto a computer or other programmable data processing apparatus to cause a series of operational steps to be performed on the computer or other programmable apparatus to produce a computer-implemented process such that the instructions which execute on the computer or other programmable apparatus provide steps for implementing the functions specified in the flowchart block or blocks.

In various embodiments, software may be stored in a computer program product and loaded into a computer system using a removable storage drive, hard disk drive, or communications interface. The control logic (software), when executed by the processor or controller, causes the processor or controller to perform the functions of various embodiments as described herein. In various embodiments, hardware components may take the form of application specific integrated circuits (ASICs). Implementation of the hardware so as to perform the functions described herein will be apparent to persons skilled in the relevant art(s).

As will be appreciated by one of ordinary skill in the art, the system may be embodied as a customization of an existing system, an add-on product, a processing apparatus executing upgraded software, a stand-alone system, a distributed system, a method, a data processing system, a device for data processing, and/or a computer program product. Accordingly, any portion of the system or a module may take the form of a processing apparatus executing code, an internet-based embodiment, an entirely hardware embodiment, or an embodiment combining aspects of the internet, software, and hardware. Furthermore, the system may take the form of a computer program product on a computer-readable storage medium having computer-readable program code means embodied in the storage medium. Any suitable computer-readable storage medium may be utilized, including hard disks, solid state storage media, CD-ROM, BLU-RAY DISC®, optical storage devices, magnetic storage devices, and/or the like.

In various embodiments, components, modules, or engines of the systems or apparatus described herein may be implemented as micro-applications or micro-apps. Micro-apps are typically deployed in the context of a mobile operating system, including for example, a WINDOWS® mobile operating system, an ANDROID® operating system, an APPLE® iOS operating system, a BLACKBERRY® operating system, and the like. The micro-app may be configured to leverage the resources of a larger operating system and associated hardware via a set of predetermined rules that govern the operation of various operating systems and hardware resources. For example, where a micro-app desires to communicate with a device or network other than the mobile device or mobile operating system, the micro-app may leverage the communication protocol of the operating system and associated device hardware under the predetermined rules of the mobile operating system. Moreover, where the micro-app desires an input from a user, the micro-app may be configured to request a response from the operating system that monitors various hardware components and then communicates a detected input from the hardware to the micro-app.

The system and method may be described herein in terms of functional block components, screen shots, optional selections, and various processing steps. It should be appreciated that such functional blocks may be realized by any number of hardware and/or software components configured to perform the specified functions. For example, the system may employ various integrated circuit components, e.g., memory elements, processing elements, logic elements, look-up tables, and the like, which may carry out a variety of functions under the control of one or more microprocessors or other control devices. Similarly, the software elements of the system may be implemented with any programming or scripting language such as C, C++, C#, JAVA®, JAVASCRIPT®, JAVASCRIPT® Object Notation (JSON), VBScript, Macromedia COLD FUSION, COBOL, MICROSOFT® company's Active Server Pages, assembly, PERL®, PHP, awk, PYTHON®, Visual Basic, SQL Stored Procedures, PL/SQL, any UNIX® shell script, and extensible markup language (XML) with the various algorithms being implemented with any combination of data structures, objects, processes, routines or other programming elements. Further, it should be noted that the system may employ any number of techniques for data transmission, signaling, data processing, network control, and the like. Still further, the system could be used to detect or prevent security issues with a client-side scripting language, such as JAVASCRIPT®, VBScript, or the like.

The various system components discussed herein may also include one or more of the following: a host server or other computing systems including a processor for processing digital data; a memory coupled to the processor for storing digital data; an input digitizer coupled to the processor for inputting digital data; an application program stored in the memory and accessible by the processor for directing processing of digital data by the processor; a display device coupled to the processor and memory for displaying information derived from digital data processed by the processor; and a plurality of databases.

As used herein, the term “network” includes any cloud, cloud computing system, or electronic communications system or method that incorporates hardware or software components. Communication among the components of the systems may be accomplished through any suitable communication channels, such as, for example, a telephone network, an extranet, an intranet, or an internet. Such communications may also occur using online communications, satellite communications, off-line communications, wireless communications, transponder communications, local area network (LAN), wide area network (WAN), or virtual private network (VPN). Moreover, the systems may be implemented with TCP/IP communications protocols, IPX, APPLETALK®, IP-6, NetBIOS, OSI, any tunneling protocol (e.g., IPsec, SSH, etc.), or any number of existing or future protocols. If the network is in the nature of a public network, such as the internet, it may be advantageous to presume the network to be insecure and open to eavesdroppers. Specific information related to the protocols, standards, and application software utilized in connection with the internet is generally known to those skilled in the art and, as such, need not be detailed herein.

Exemplary systems and methods may be described herein with reference to screen shots, block diagrams and flowchart illustrations of methods, apparatus, and computer program products according to various embodiments. It will be understood that each functional block of the block diagrams and the flowchart illustrations, and combinations of functional blocks in the block diagrams and flowchart illustrations, respectively, can be implemented by computer program instructions.

Accordingly, functional blocks of the block diagrams and flowchart illustrations support combinations of means for performing the specified functions, combinations of steps for performing the specified functions, and program instruction means for performing the specified functions. It will also be understood that each functional block of the block diagrams and flowchart illustrations, and combinations of functional blocks in the block diagrams and flowchart illustrations, can be implemented by either special purpose hardware-based computer systems which perform the specified functions or steps, or suitable combinations of special purpose hardware and computer instructions.

System program instructions and/or controller instructions may be loaded onto a non-transitory, tangible computer-readable medium having instructions stored thereon that, in response to execution by a controller, cause the controller to perform various operations. The term “non-transitory” is to be understood to remove only propagating transitory signals per se from the claim scope and does not relinquish rights to all standard computer-readable media that are not only propagating transitory signals per se. Stated another way, the meaning of the term “non-transitory computer-readable medium” and “non-transitory computer-readable storage medium” should be construed to exclude only those types of transitory computer-readable media which were found in In Re Nuijten to fall outside the scope of patentable subject matter under 35 U.S.C. § 101.

Benefits, other advantages, and solutions to problems have been described herein with regard to specific embodiments. Furthermore, the connecting lines shown in the various figures contained herein are intended to represent exemplary functional relationships and/or physical or communicative couplings between the various elements. It should be noted that many alternative or additional functional relationships or physical or communicative connections may be present in a practical system. However, the benefits, advantages, solutions to problems, and any elements that may cause any benefit, advantage, or solution to occur or become more pronounced are not to be construed as critical, required, or essential features or elements of the disclosure. The scope of the disclosure is accordingly to be limited by nothing other than the appended claims, in which reference to an element in the singular is not intended to mean “one and only one” unless explicitly so stated, but rather “one or more.” Moreover, where a phrase similar to “at least one of A, B, or C” or “at least one of A, B, and C” is used in the claims or specification, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C. Different cross-hatching may be used throughout the figures to denote different parts but not necessarily to denote the same or different materials.

Methods, systems, and articles are provided herein. In the detailed description herein, references to “one embodiment”, “an embodiment”, “various embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments.

Furthermore, no element, component, or method step in the present disclosure is intended to be dedicated to the public regardless of whether the element, component, or method step is explicitly recited in the claims. No claim element herein is to be construed under the provisions of 35 U.S.C. 112 (f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A method, comprising:
receiving, by a battery fault detection system, historical operational data associated with a high voltage battery system of a vehicle, wherein the historical operational data comprises at least one of a maximum cell voltage or a minimum cell voltage;
preparing, by the battery fault detection system, the historical operational data for input into a trained predicted operation model;
modeling, by the trained predicted operation model, predicted operational data of the high voltage battery system based on the historical operational data, wherein the predicted operational data comprises at least one of a predicted maximum cell voltage or a predicted minimum cell voltage;
comparing, by the battery fault detection system, the historical operational data and the predicted operational data;
determining, by the battery fault detection system, the existence of a thermal runaway fault based on the comparison between the historical operational data and the predicted operational data; and
based on the determining the existence of a thermal runaway fault, transmitting, by the battery fault detection system, a thermal runaway fault message.

2. The method of claim 1, further comprising receiving, by the battery fault detection system, initial characterization data associated with the high voltage battery system, wherein the initial characterization data includes data regarding one or more components of the high voltage battery system, and wherein the modeling predicted operational data is based at least in part on the initial characterization data.

3. The method of claim 1, further comprising communicating, by the battery fault detection system and to a user application associated with a user of the vehicle, the thermal runaway fault message.

4. The method of claim 1, wherein the high voltage battery system comprises:
a battery management system (BMS); and
a plurality of battery packs, each battery pack in the plurality of battery packs comprising a plurality of battery modules, each battery module in the plurality of battery modules comprising a plurality of battery blocks, and each battery block in the plurality of battery blocks comprising a plurality of battery cells.

5. The method of claim 4, wherein the thermal runaway fault identifies a specific battery pack in the plurality of battery packs as a faulted battery pack.

6. The method of claim 5, further comprising disconnecting, by the BMS, the faulted battery pack from the remaining battery packs in the plurality of battery packs.

7. The method of claim 6, further comprising at least partially discharging the faulted battery pack to below a threshold state of charge (SOC).

8. The method of claim 7, wherein the at least partially discharging the faulted battery pack comprises using the faulted battery pack to at least partially charge one or more of the other battery packs in the plurality of battery backs.

9. The method of claim 7, wherein the at least partially discharging the faulted battery pack comprises delivering current from the faulted battery pack to a brake resistor of the vehicle.

10. The method of claim 7, wherein the at least partially discharging the faulted battery pack comprises delivering current from the faulted battery pack to operate at least one of a pump or a fan of the vehicle.

11. The method of claim 1, further comprising setting, by a vehicle control module of the vehicle, the vehicle into a “limp-home” mode whereby at least one of current draw from the high voltage battery system or top speed of the vehicle are limited.

12. The method of claim 1, further comprising increasing, responsive to the thermal runaway fault and by a thermal management system of the vehicle, cooling of the high voltage battery system to reduce the temperature of one or more components thereof.

13. The method of claim 4, wherein the trained predicted operation model comprises a convolutional neural network (CNN) or a long short-term memory (LSTM) deep learning algorithm.

14. The method of claim 13, wherein the historical operational data is obtained through a measurement obtained by a plurality of sensors in the high voltage battery system.

15. The method of claim 14, wherein each sensor in the plurality of sensors is coupled directly or indirectly to a corresponding battery cell.

16. The method of claim 1, wherein receiving, by the battery fault detection system, historical operational data comprises receiving the historical operational data from an electronic control unit (ECU) of the vehicle.

17. The method of claim 1, wherein preparing, by the battery fault detection system, the historical operational data comprises comparing a difference between the maximum cell voltage and the minimum cell voltage to a voltage threshold, and
wherein preparing, by the battery fault detection system, the historical operational data comprises adding, by the battery fault detection system, the voltage threshold to the minimum cell voltage to determine an adjusted maximum cell voltage.

18. The method of claim 17, wherein preparing, by the battery fault detection system, the historical operational data comprises subtracting, by the battery fault detection system, the voltage threshold from the maximum cell voltage to determine an adjusted minimum cell voltage.

19. The method of claim 18, wherein the battery fault detection system and the trained prediction operation model are operative on one or more processors onboard the vehicle.

20. The method of claim 18, wherein the battery fault detection system and the trained prediction operation model are disposed remotely from the vehicle and are in communicative connection therewith via a secure wireless network connection.
